(19) United States
(12) Patent Application Publication
(10) Pub. No.: US 2016/0093489 A1
(43) Pub. Date: Mar. 31, 2016

(54) METHOD OF FORMING A DIELECTRIC LAYER

(71) Applicant: UNITED MICROELECTRONICS CORP., Hsin-Chu City (TW)

(72) Inventors: Yu-Feng Liu, Tainan City (TW); Chih-Wei Yang, Kaohsiung City (TW); Jian-Cun Ke, Tainan City (TW); Chia-Fu Hsu, Tainan City (TW)

(21) Appl. No.: 14/499,268

(22) Filed: Sep. 29, 2014

(51) Int. Cl. H01L 21/02; H01L 29/51

(52) U.S. Cl. CPC H01L 21/02247; H01L 21/02329; H01L 29/517; H01L 29/518; H01L 29/511; H01L 21/02252; H01L 21/02255

(57) ABSTRACT

A method of forming a dielectric layer includes the following steps. First of all, a high-k dielectric layer is formed on a substrate. Next, a nitridation process is performed on the high-k dielectric layer immediately after the high-k dielectric layer is formed. Then, a post-nitridation process is performed on the high-k dielectric layer after the nitridation process is performed.

### BACKGROUND OF THE INVENTION

1. Field of the Invention

The present invention relates to a method of forming a dielectric layer, and more particularly to a method of forming a high-k dielectric layer that improves on leakage penalty and instability issues.

2. Description of the Prior Art

Poly-silicon is conventionally used as a gate electrode in semiconductor devices, such as metal-oxide-semiconductors (MOS). With the trend towards scaling down the size of semiconductor devices, the conventional poly-silicon gate faces problems such as low performances due to boron penetration, and an unavoidable depletion effect that increases the equivalent thickness of the gate dielectric layer, reduces the gate capacitance, and worsens a driving force of the devices. Therefore, work function metals are used to replace the conventional poly-silicon gates as control electrodes that are suitable as high-k dielectric layers.

The high-k dielectric layer is usually composed of high-k materials, such as metal oxide, which has the potential to form a silicon oxide comparable interface with the silicon substrate. Such high-k materials are still unsatisfactory, however, especially for their electrical and material properties. For example, it is found that the interface between the high-k materials and silicon has a high interface trap density, and the high-k materials are thermally unstable at high temperatures.

Thus, there is a need for improving on dielectric layer formation techniques by which high quality gate dielectric layer and interfaces can be obtained.

### SUMMARY OF THE INVENTION

It is one of the primary objectives of the present invention to provide a method of forming a dielectric layer, which can solve the aforementioned issues of the high-k materials, to thereby dramatically improve the interface trap density and thermal instability.

To achieve the above purpose, the present invention provides a method of forming a dielectric layer comprising the following steps. First of all, a high-k dielectric layer is formed on a substrate. Next, a nitridation process is performed on the high-k dielectric layer immediately after the high-k dielectric layer is formed. Then, a post-nitridation process is performed on the high-k dielectric layer after the nitridation process is performed.

The nitridation process under oxygen free conditions is carried out immediately after that high-k dielectric layer is formed firstly, for isolating the high-k dielectric layer from oxygen and temperatures higher than room temperature, so that the thermal instability issues of the high-k dielectric layer can be significantly improved. In addition, the post-nitridation process under diluted oxygen conditions (less than 10% oxygen) is further carried out after the nitridation process of the present invention, which effectively reduces the interface trap density of the high-k dielectric layer. Thus, the method of the present invention can improve on both the interface trap and the thermal instability issues of the high-k materials.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 2 are cross-sectional views illustrating a semiconductor device at various stages of a method of forming a dielectric layer according to a first preferred embodiment of the present invention.

FIG. 3 to FIG. 4 are schematic cross-sectional views illustrating a semiconductor device at various stages of a method of forming a dielectric layer according to another preferred embodiment of the present invention.

FIG. 5 to FIG. 6 are schematic diagrams illustrating a method of forming a MOSFET in a gate-first process according to a preferred embodiment of the present invention.

FIG. 7 to FIG. 9 are schematic diagrams illustrating a method of forming a MOSFET in a high-k first, gate-last process according to a preferred embodiment of the present invention.

FIG. 10 is a schematic diagram illustrating a method of forming a MOSFET in a high-k last, gate-last process according to a preferred embodiment of the present invention.

### DETAILED DESCRIPTION

In the following description, numerous specific details, and accompanying drawings are given to provide a thorough understanding of the invention. It will, however, be apparent to one skilled in the art that the invention may be practiced without these specific details.

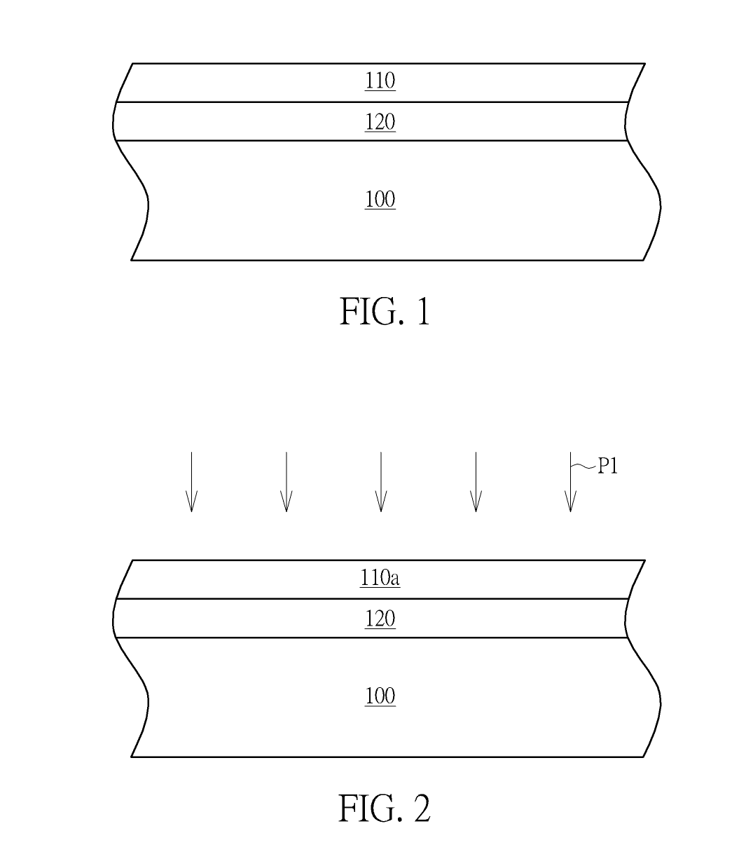

FIGS. 1-2 are cross-sectional views illustrating a semiconductor device at various stages of a method of forming a dielectric layer according to a first preferred embodiment of the present invention. Firstly, as shown in FIG. 1, a high-k dielectric layer 110 is formed on a substrate 100. The high-k dielectric layer 110 may include a binary metal oxide layer, including at least one of hafnium dioxide (HfO₂), zirconium oxide (ZrO₂), lanthanum oxide (La₂O₃), yttrium oxide (Y₂O₃), titanium oxide (TiO2) and a silicate or aluminate of at least one of the aforementioned binary metal oxide, or a metal oxynitrides layer, including at least one of aluminum oxynitride (ALON), zirconium oxynitride (ZrON), hafnium oxynitride (HfON), lanthanum oxynitride (LaON), yttrium oxynitride (YON), and a silicate or aluminate of at least one of the aforementioned metal oxynitrides, which are formed by using a deposition technique, such as chemical vapor deposition (CVD), physical vapor deposition (PVD), atomic layer deposition (ALD), or molecular beam epitaxy (MBE), but not limited thereto. In a preferred embodiment, an interfacial layer 120 may be optionally formed between the substrate 100 and the high-k layer 110, wherein the interfacial layer 120 may be a silicon dioxide layer formed by an in situ steam generation (ISSG) oxidation process, but not limited thereto.

Next, as shown in FIG. 2, an annealing process P1 is performed on the high-k dielectric layer 110, to form a high-k dielectric layer 110a. The annealing process P1 is performed at a temperature substantially between 300° C. and 1000° C., under oxygen conditions. The high-k dielectric layer 110a is formed in a manner that allows having reduced interface trap density. Through the annealing process P1 of the present embodiment, the aforementioned interface trap density issue of the high-k materials may be improved, thereby obtaining improved quality of high-k dielectric layer.

The present invention is not limited thereto, and the following description will detail different embodiments of the method of the present invention. To simplify the description, the following description will detail dissimilarities among the different embodiments; identical features will not be redundantly described. In order to compare the differences between the embodiments easily, identical components in each of the following embodiments are marked with identical symbols.

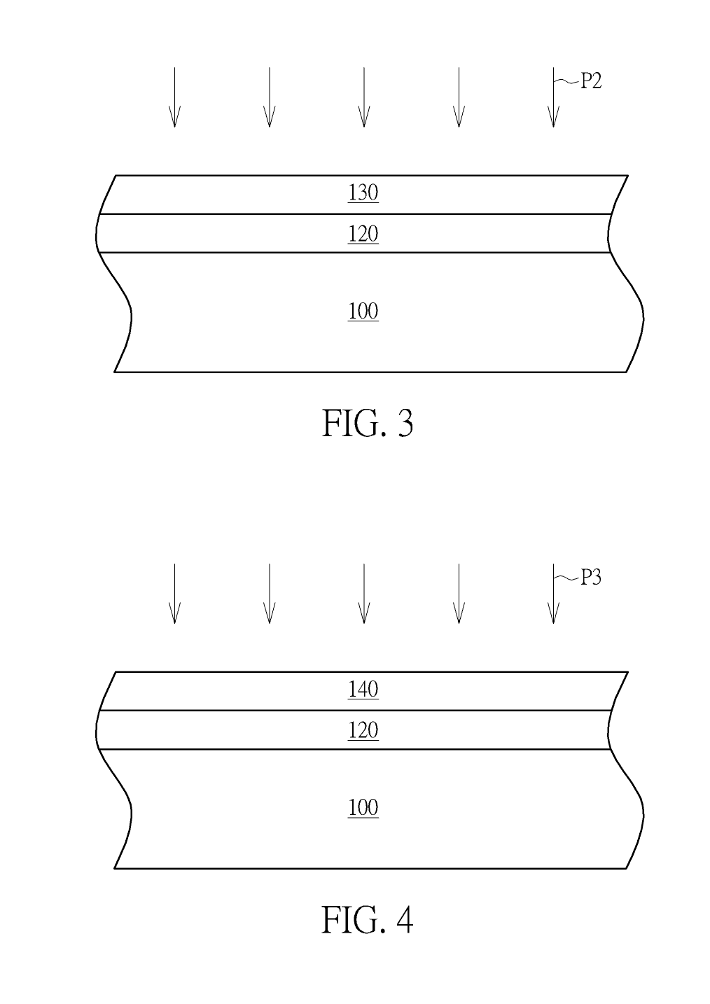

FIGS. 3-4 are schematic cross-sectional views illustrating a semiconductor device at various stages of a method of forming a dielectric layer according to another preferred embodiment of the present invention. As shown in FIG. 3, and in comparison with the aforementioned embodiment, a nitridation process P2 is directly performed on the high-k dielectric layer 110 shown in FIG. 1, immediately after the high-k dielectric layer 110 is formed. The nitridation process P2 is performed under oxygen free conditions, to convert the high-k dielectric layer 110 into a nitridated high-k dielectric layer 130. Preferably, the nitridation process P2 is performed at a low temperature, such as room temperature, i.e. substantially between 20° C. and 25° C. In one embodiment, the nitridation plasma for performing the nitridation process is generated by a remote nitridation source, and then introduced into a nitridation chamber (not shown in the drawings). In another embodiment, the nitridation process is a decoupled plasma nitridation (DPN) process, but not is limited thereto.

Then, as shown in FIG. 1 and FIG. 4, a post-nitridation process P3 is performed after the nitridation process is performed. The post-nitridation process P3 of the present embodiment is preferably performed under conditions containing a small amount of oxygen; preferably less than 10% oxygen, and more preferably around 1% oxygen, to obtain a matured high-k dielectric layer 140. The post-nitridation process P3 is preferably performed oxygen diluted with inert gas, wherein the aforementioned inert gas includes nitrogen and argon, but is not limited thereto. In one embodiment, the post-nitridation process is a post-nitridation annealing process carried out at 700° C. to 1000° C., and preferably at 900° C., but not limited thereto.

The present invention directly performs the nitridation process on the high-k dielectric layer immediately after the high-k dielectric layer is formed, so that the high-k dielectric layer will be nitridated instantly under oxygen free conditions, and the lower temperature, immediately after formation. The post-nitridation process (with diluted oxygen) is then performed on the high-k dielectric layer under higher temperature conditions. In other words, the high-k dielectric layer of the present invention will not contact either oxygen or high temperature conditions, unless the nitridation process has been performed previously. Through such previous nitridation processes, the crystallization temperature of the high-k dielectric layer will be significantly improved, such that the high-k dielectric layer will become more thermally stable in the following manufacturing processes. Accordingly, the interface trap density of the high-k dielectric layer of the present invention can be more effectively reduced in the following post-nitridation processes, by using oxygen diluted with inert gas approximately less than 10%. The method of the present invention can improve both the interface trap density and the thermal instability issues of the high-k materials.

Through the method of forming the dielectric layer according to the present invention, the gate dielectric layer with improved qualities can be obtained, said improved qualities including preferable thermal stability, better element performance, and better leakage improvement. The dielectric layer obtained from the method of the present invention can also achieve higher breakdown voltage, for example with at least 50 mV improvement, and increased characteristics of positive bias temperature instability, for example to 1.09V. Furthermore, the method of the present invention is easy to be performed, and can thereby save on manufacturing time and costs.

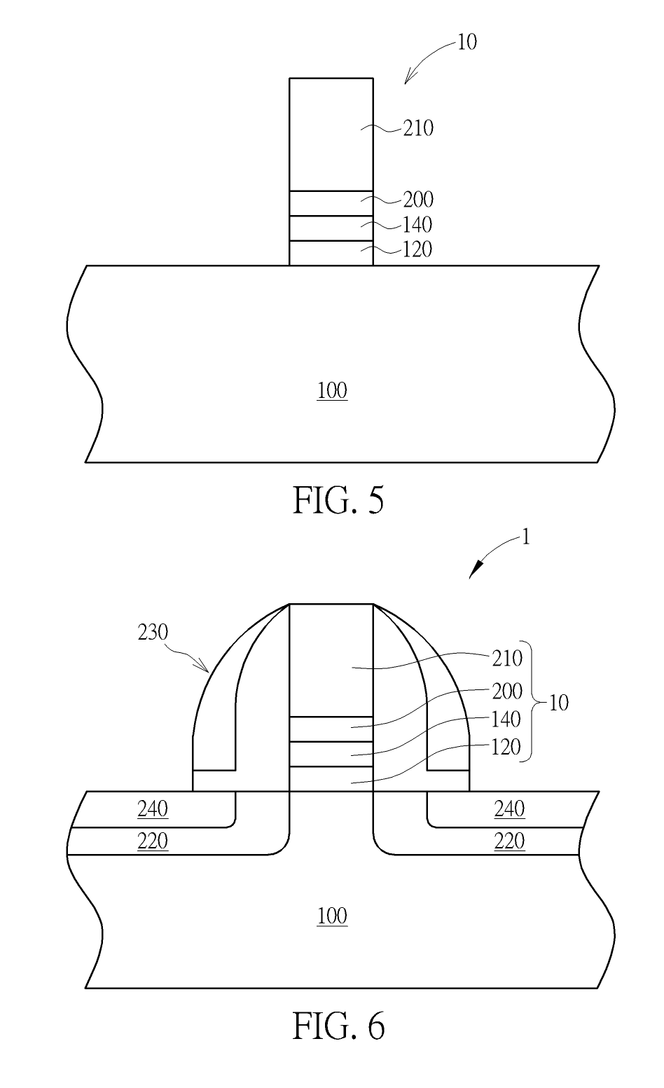

The following description will further illustrate a preferred embodiment of the method of the present invention applied to a method of forming a MOSFET in a gate-first process. Referring to FIGS. 5 to 6. Firstly, a work function material layer (not shown in the drawings) and a metal material layer (not shown in the drawings) are sequentially formed on the high-k dielectric layer 140 shown in FIG. 4. Then, as shown in FIG. 5, the aforementioned metal material layer, work function material layer, the high-k dielectric layer 140 and the interfacial layer 120 are patterned to define a gate structure 10 including a metal layer 210, a work function layer 200, and patterned high-k dielectric layer 140 and interfacial layer 120. As shown in FIG. 6, the remaining structures of the MOSFET 1 (for example, a light doped drain (LDD) region 220, a spacer 230, a source/drain region 240 and so on) are formed accordingly, to form the MOSFET 1. In one embodiment, the work function layer is a P type work function metal layer which serves as a work function metal in a P-type transistor, and which may include Ni, Pd, Pt, Be, Ir, Te, Re, Ru, Rh, W, Mo, or WN, RuN, MoN, TiN, TaN, or WC, TaC, TiC, or TiAlN, TaAlN, but is not limited thereto. In another embodiment, the work function layer is an N type work function metal layer which serves as a work function metal in a N-type transistor, and which may include titanium aluminides (TiAl), aluminum zirconium (ZrAl), aluminum tungsten (WAl), aluminum tantalum (TaAl) or aluminum hafnium (HfAl), but is not limited thereto. In another embodiment, a barrier layer (not shown in the drawings), such as a TaN layer or a TiN layer, may be optionally formed between the work function layer and the high-k dielectric layer.

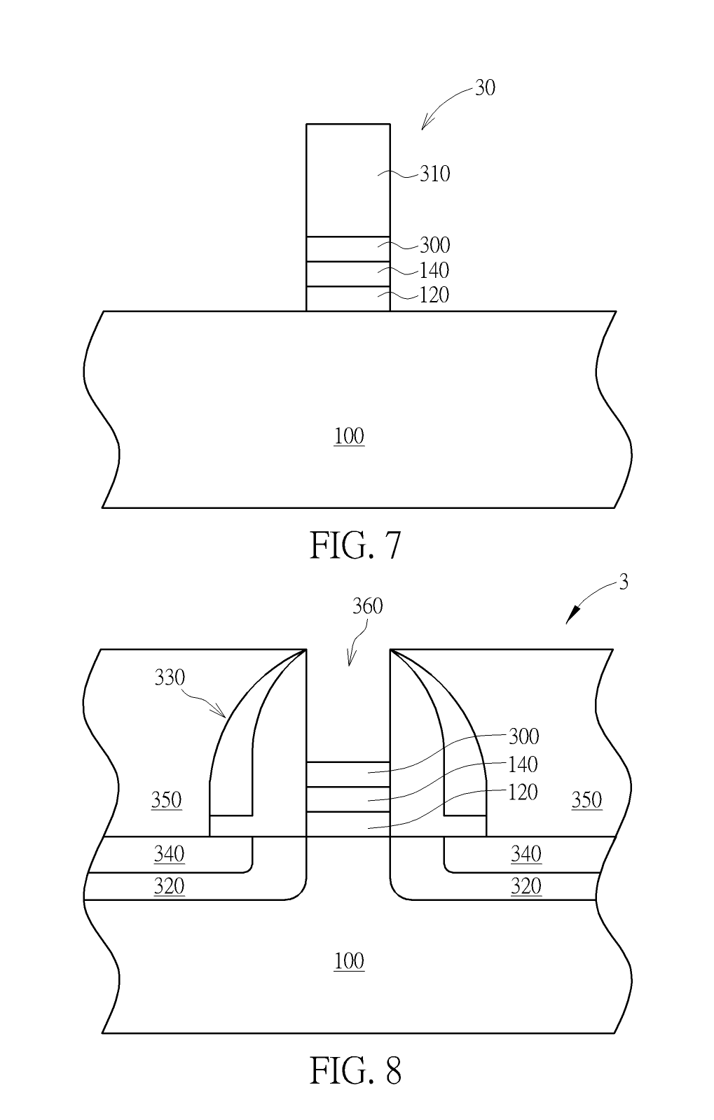

The next description will illustrate a preferred embodiment of the method of the present invention applied to a method of forming a MOSFET in a high-k first, gate-last process. Refer to FIGS. 7 to 9. Firstly, as shown in FIG. 7, a barrier layer 300 is formed on the high-k dielectric layer 140 shown in FIG. 4, wherein the barrier layer 300 may include silicon nitride SiN, but is limited thereto. Next, a dummy gate layer 310, for example a polysilicon layer, is formed on the barrier layer 300. After that, the dummy gate layer 310, the barrier layer 300, and the aforementioned interfacial layer 120 and the high-k dielectric layer 140, are patterned to define a dummy gate structure 30 shown in FIG. 7. Then, as shown in FIG. 8, after the remaining structures of the MOSFET 3 (for example, a light doped drain (LDD) region 320, a spacer 330, a source/drain region 340, an interlayer dielectric (ILD) layer 350 and so on) are formed sequentially. The dummy gate layer 310 is removed by using the barrier layer 300 as an etching stop layer to form a gate trench 360. Finally, as shown in FIG. 9, after the barrier layer 300 is removed, a work function layer 370 and a metal layer 380 are filled into the gate trench 360, thereby forming the MOSFET 3. Please note that the material properties of the work function layer 370 of the present preferred embodiment are similar to that of the work function layer of the above mentioned embodiment, and will therefore not be redundantly described herein.

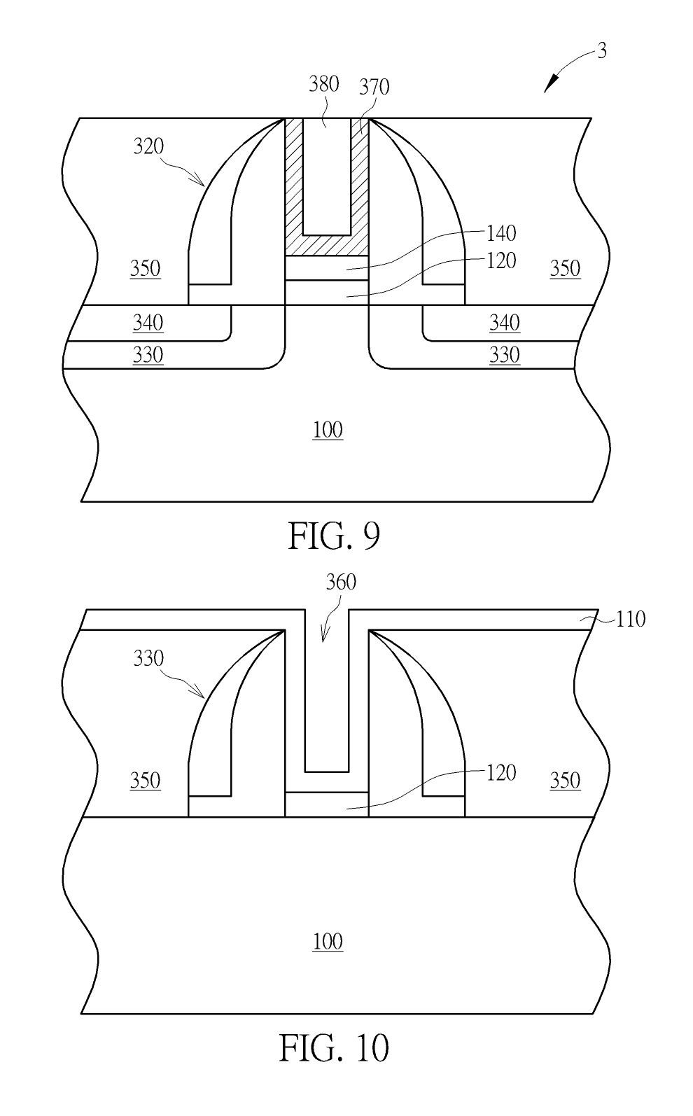

FIG. 10 is a schematic diagram illustrating a method of forming a MOSFET in a high-k last, gate-last process according to a preferred embodiment of the present invention. In comparison with the aforementioned embodiment shown in FIGS. 7-9, the interfacial layer 120 and the high-k dielectric layer 110 of the present embodiment are formed after the dummy gate structure is completely removed, with the high-k dielectric layer 110 being filled in the gate trench 360 and disposed on the interfacial layer 120, as shown in FIG. 10. In one preferred embodiment, the dummy gate structure includes a dummy interfacial layer (not shown in the drawings), and the interfacial layer is formed after completely removing the dummy interfacial layer. In another embodiment of the present invention, the dummy interfacial layer may optionally remain to function as the interfacial layer. After that, the aforementioned nitridation process P2 and the post-nitridation process P3 are performed sequentially on the high-k dielectric layer 110. After a planarization process, such as a chemical mechanic planarization (CMP) process, is performed to form a U-shaped high-k dielectric layer (not shown in the drawings) in the gate trench 360, the remaining structure of the MOSFET (such as a work function metal layer and a metal gate layer) may be formed sequentially. Note that, since the material properties and forming method of the work function layer and the metal layer in the present preferred embodiment are all similar to that of the work function layer and the metal layer of the aforementioned embodiment shown in FIG. 9, details will not be redundantly described herein.

In summary, the method of forming the dielectric layer according to the present invention carries out a nitridation process under oxygen free conditions immediately after the high-k dielectric layer is formed, isolating the high-k dielectric layer from oxygen and temperatures higher than room temperature, such that the thermal instability issues of the high-k dielectric layer can be significantly improved. In addition, the method of the present invention further carries out a post-nitridation process under diluted oxygen conditions (less than 10% oxygen) after the nitridation process, to effectively reduce the interface trap density of the high-k dielectric layer. Thus, the method of the present invention may be applied to both gate first and gate last fabrication processes of a MOSFET, to improve the interface trap and thermal instability issues of the high-k materials.

Those skilled in the art will readily observe that numerous modifications and alterations of the device and method may be made while retaining the teachings of the invention. Accordingly, the above disclosure should be construed as limited only by the metes and bounds of the appended claims.

1. A method of forming a dielectric layer comprising:
forming a high-k dielectric layer on a substrate;
performing a nitridation process on the high-k dielectric layer immediately after forming the high-k dielectric layer, wherein the whole nitridation process is performed at room temperature; and
performing a post-nitridation process after performing the nitridation process, wherein the post-nitridation process is performed under oxygen diluted with inert gas.

2. The method of forming the dielectric layer according to claim 1, wherein the nitridation process is performed in an oxygen free environment.

3. (canceled)

4. The method of forming the dielectric layer according to claim 1, wherein the nitridation process is performed substantially between 20° C. and 25° C.

5. The method of forming a dielectric layer according to claim 1, wherein the nitridation process is a decoupled plasma nitridation process.

6. (canceled)

7. The method of forming the dielectric layer according to claim 1, wherein the post-nitridation process is performed under oxygen diluted with nitrogen conditions.

8. The method of forming the dielectric layer according to claim 1, wherein the post-nitridation process is performed under oxygen diluted with argon conditions.

9. The method of forming the dielectric layer according to claim 1, wherein the post-nitridation process is performed with less than 10% oxygen.

10. The method of forming the dielectric layer according to claim 9, wherein the post-nitridation process is performed with less than 1% oxygen in nitrogen.

11. The method of forming the dielectric layer according to claim 1, wherein the post-nitridation process is a post nitridation annealing process.

12. The method of forming the dielectric layer according to claim 1, wherein the post nitridation annealing process is carried out at 900° C.

13. The method of forming the dielectric layer according to claim 1, further comprising:
forming an interfacial layer on the substrate, between the high-k dielectric layer and the substrate.
